(19) United States
(12) Patent Application Publication
(10) Pub. No.: US 2004/0195585 A1
(43) Pub. Date: Oct. 7, 2004

(54) Multi-gate heterostructured field effect transistor

(75) Inventors: Samson Mil'shtein, Chelmsford, MA (US); Peter Ersland, Littleton, MA (US); Shivarajiv Kumar Somisetty, Lowell, MA (US); Carlos Gil, Billerica, MA (US)

Correspondence Address: HAMILTON, BROOK, SMITH & REYNOLDS, P.C., 530 VIRGINIA ROAD, P.O. BOX 9133, CONCORD, MA, 01742-9133, US

(73) Assignees: University of Massachusetts Lowell, Lowell, MA (US); M/A-COM, Lowell, MA (US)

(21) Appl. No.: 10/729,426

(22) Filed: Dec. 5, 2003

Related U.S. Application Data
(60) Provisional application No. 60/431,631, filed on Dec. 5, 2002.

(51) Int. Cl. H01L 31/0328

(52) U.S. Cl. 257/192

(57) ABSTRACT

A heterostructured field effect transistor has a multi-gate configuration, in which the gate voltages are individually biased to tailor the potential field. The multi-gate configuration can be a two-, three-, or four-gate configuration. The transconductance of the transistor can be substantially linear over a range of gate voltages.

### RELATED APPLICATION

This application claims the benefit of U.S. Provisional Application No. 60/431,631, filed on Dec. 5, 2002, the entire teachings of which are incorporated herein by reference.

### BACKGROUND

A large class of Heterostructured Field Effect Transistors (HFETs) includes Modulation Doped Field Transistors (MODEFETs), High Electron Mobility Transistors (HEMT), Two-Dimensional Electron Gas Field Effect Transistors (TEGFETs), and Selectively Doped Heterostucture Transistors (SDHTs) among others. All of these have a non-uniform heterostructure (interface) potential along a channel of a HFET. As in the case with a non-uniform electrical field in conventional FETs, a non-uniformity of this heterostucture potential limits the gain gₘ and operational frequency fₜ, increases the level of noise, and has a significant impact on the non-linearity of the gain.

Recently, some have proposed Transistors with Tailored Field (TTF) that have the ability to manipulate the electrical field in FETs using external biases, which have led to an increased average velocity of the electrons, and, therefore, a shorter transit time.

### SUMMARY

A heterostructured field effect transistor has a multi-gate configuration, in which the gate voltages are individually biased to tailor the potential field. The multi-gate configuration can be a two-, three-, or four-gate configuration. The transconductance of the transistor can be substantially linear over a range of gate voltages.

### BRIEF DESCRIPTION OF THE DRAWINGS

The foregoing and other objects, features and advantages of the invention will be apparent from the following more particular description of preferred embodiments of the invention, as illustrated in the accompanying drawings in which like reference characters refer to the same parts throughout the different views. The drawings are not necessarily to scale, emphasis instead being placed upon illustrating the principles of the invention.

FIG. 1 is a cross-sectional view a semiconductor transistor.

FIG. 2 is a plot of transfer (Id) and transconductance (gₘ) curves for p-HEMT in tailored (non-shaded squares and triangles) and non-tailored field regimes (solid squares and triangles) of operation.

FIG. 3 is a plot of the I-V characteristics for p-HEMT in a non-tailored regime of operation.

FIG. 4 is a plot of the I-V characteristics for p-HEMT in tailored field regime of operation.

### DETAILED DESCRIPTION OF THE INVENTION

A description of preferred embodiments of the invention follows.

Conventional heterostructure transistors like High Electron Mobility Transistor (HEMT) operate rather differently than metal semiconductor field effect transistor (MESFET). In HEMTs, the electrons are injected into an intrinsic layer of a semiconductor material and are confined into a two-dimensional space of a heterostructure potential φ. At a given temperature, the mobility of the injected electrons is the highest along the intrinsic layer, which improves power performance and increases the frequency of operation, fₜ.

Quantization of electron energy in a two dimensional (2D) electron gas follows the equation:

$${E}_{n} = \frac{π {ℏ}^{2} {n}^{2}}{2 {m}^{*} {W}^{2}} \qquad ( 1 )$$

where [symbol] is the reduced Planck's constant, m* is the effective mass of an electron, n is the quantum number, W is the width of the triangle heterostructure pontential, or quantum well. The number of energy subbands Eₙ and their value define the distribution of electrons in the channel. Presence of discrete energy levels leads to reduction of noise, and may minimize hot electron damage, if subbands with high energy are not available in the 2D electron gas. This, however, is not realized in existing designs of HEMTs.

The energy and electron wave function can be defined from an equation such as

$$\sqrt{\frac{2 {m}^{*} E}{{ℏ}^{2}}} tan ( \sqrt{\frac{2 {m}^{*} E}{{ℏ}^{2}}} \frac{W}{2} ) = \sqrt{\frac{2 {m}^{*} ( ϕ ( x ) - E )}{{ℏ}^{2}}} \qquad ( 2 )$$

where E is the energy of the electron, and the heterostructure potential (p is provided by the equation:

φ(x)=V_{bi},+V_{D}−V_{G} (3)

Hence, with no drain bias V_{D} the heterostructure potential φ is equal to the built-in potential V_{bi} plus the gate bias V_{G}, and the potential φ is uniform in height and shape along the channel. Thus, when V_{G}=0, φ=V_{bi}, so that basic energy subbands are present. But with applied gate and drain biases, V_{G} and V_{D}, the potential φ(x)=f(V_{G}, V_{D}) becomes a complicated, non-uniform function of the terminal voltages.

The drawbacks of HEMTs are well known. Like MESFETs, electrons in HEMTs move slowly from the source along a substantial portion of a channel, while any applied biases change the width of the quantum well since the width is a function of the drain and gate biases, i.e. W=f(V_{G}, V_{D}). Such applied biases modify the spectra of energy subbands along the channel. Although the transcendental equation (2) is typically solved by numerical methods, a simple assessment shows that at the source side, where φ(x)=V_{bi}+V_{G}, the respective subbands for n=1, 2, 3 are

E₁=0.015 eV

E₂=0.06 ev

E₃=0.15 eV

However, E₃ does not actually exist because E₃>q φ, where q is the electron charge.

At the drain side, where, for example, V_{D}=6V to 8V, the subbands for n=1, 2, 3 are

E₁=1.5 eV

E₂=6 eV

E₃=13 eV

and E4>q φ.

As a cluster of electrons moves along the channel, the energy distribution of the electrons occurs, causing noise phenomena and hot electron damage. However, in the case of tailoring, the population of energy levels in the 2D electron gas is the same. Electrons moving through the channel will face decreased impurity scattering because of the intrinsic nature of the material, but they will still face phonon scattering. However, based on the calculations described above, the electron energies (energy levels) will vary along the channel, generating noise.

At operation frequencies, fₜ, of about 5 GHz, hot electron damage typical occurs, and the noise level is about 2 dB for certain performers in the class of heterostructure devices.

Contrary to existing HEMT designs, here, a multi-gate (two, three, and four gates) HFET configuration is used, where a more uniform potential field φ(x) is created by balancing the gate voltages. Tailoring of the potential along the channel of HEMT creates uniform distribution of energy subbands. The uniform potential accelerates the electrons as they are injected into the channel. As a result, the average electron velocity, as well as the frequency of operation fₜ, increases. The values of the energy subbands are limited and are about the same along the channel, thereby minimizing noise and hot electron damage.

Although dual-gate HEMTs are known, these are mostly used for cascade circuits, i.e. using two transistors in one, but not for tailoring the heterostructure potential.

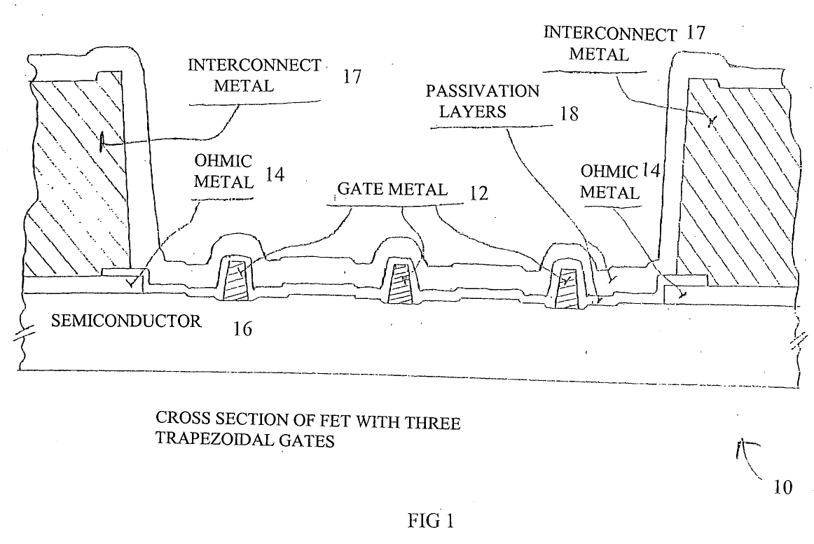

In the illustrated embodiment, transistors with the special trapezoidal gate design are used, such as the gates 12 shown in FIG. 1. The trapezoidal shape of the gates and the top metalization allows placing two submicron gates very close together, which improves the efficiency of tailoring.

In the various embodiments, the heterostructure transistors are manufactured with two, three, and four gates. The tailored tri-gate embodiment 10 is fabricated on M/A-COM's high volume production AlGaAs/InGaAs process. AuGe/Ni/Au ohmic contacts 14 are formed in a heavily-doped GaAs cap layer 16. Gates 12 that are 0.5 μm in length are optically patterned and realized with a Ti/Pt/Au metal lift-off process in a double recessed channel. Interconnects 17 are positioned over respective contacts 14, and the entire die is covered with a Si₃N₄ passivation layer 18. In the present invention, the gates 12 are individually biased with a respective potential, while in a conventional design the gates 12 are connected together such that the same potential is applied to all three gates.

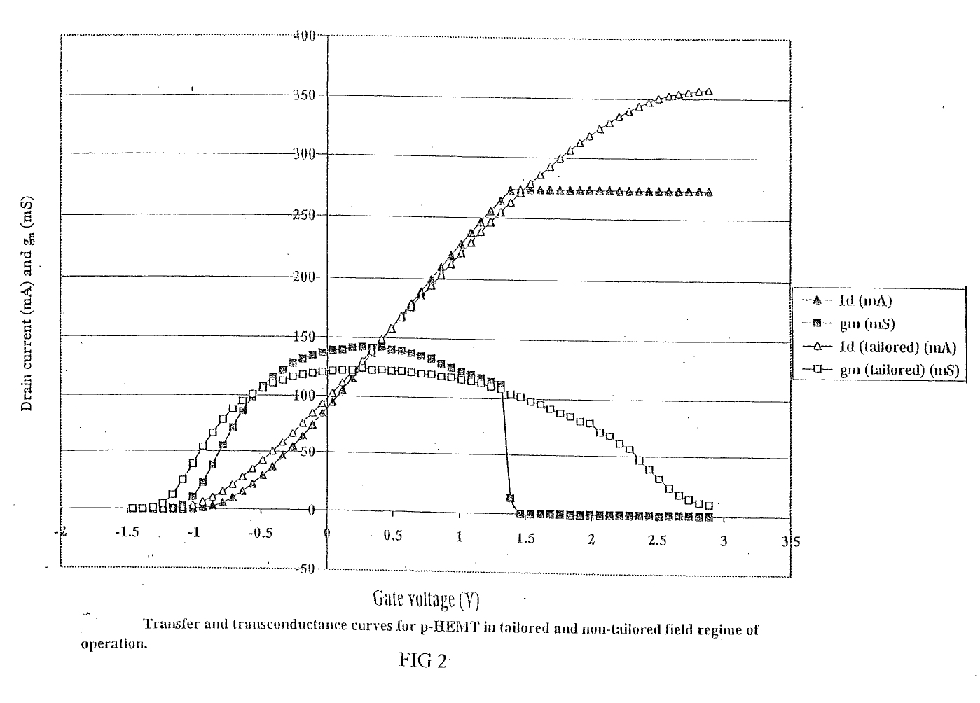

Referring now to FIGS. 2-4, there is shown a comparison of the I-V characteristics of a tailored tri-gate structure with a conventional tri-gate design. The bias of the gates in the tri-gate structure is provided in a manner that makes the heterostructure potential uniform. The variation of electron energies are minimized by making the width of the heterostructure barrier more uniform along the channel. This is accomplished by tailoring the field, that is, by making the slope of the 2D electron gas barrier more uniform along the channel. This allows the electrons to be energetic at the source, while not exceeding the energies that cause hot electron damage.

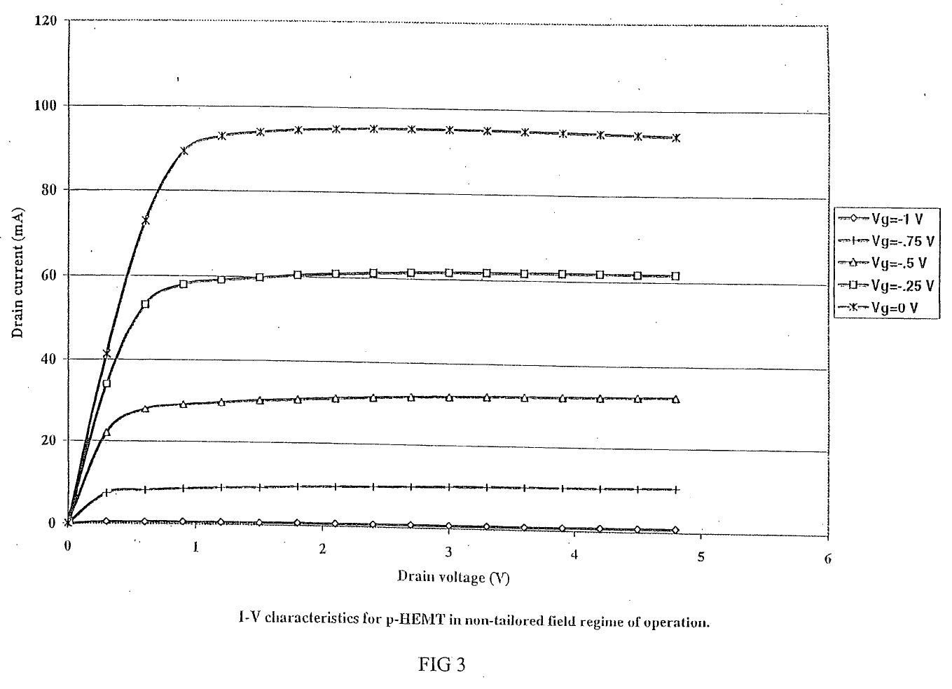

The I-V characteristics of a tri-gate HEMT for a case when three gates are connected together, i.e. non-tailored, are shown in FIG. 3, emulating the operation of a single gate convential HEMT as well as a tri-gate switch. FIG. 3 shows the drain current versus drain voltage, V_{D}, for various gate biases or voltages, V_{G}. As can be seen, the spacing between the I-V curves changes. Accordingly, the transconductance (gₘ) is non-linear as shown by the plot of the solid squares in FIG. 2.

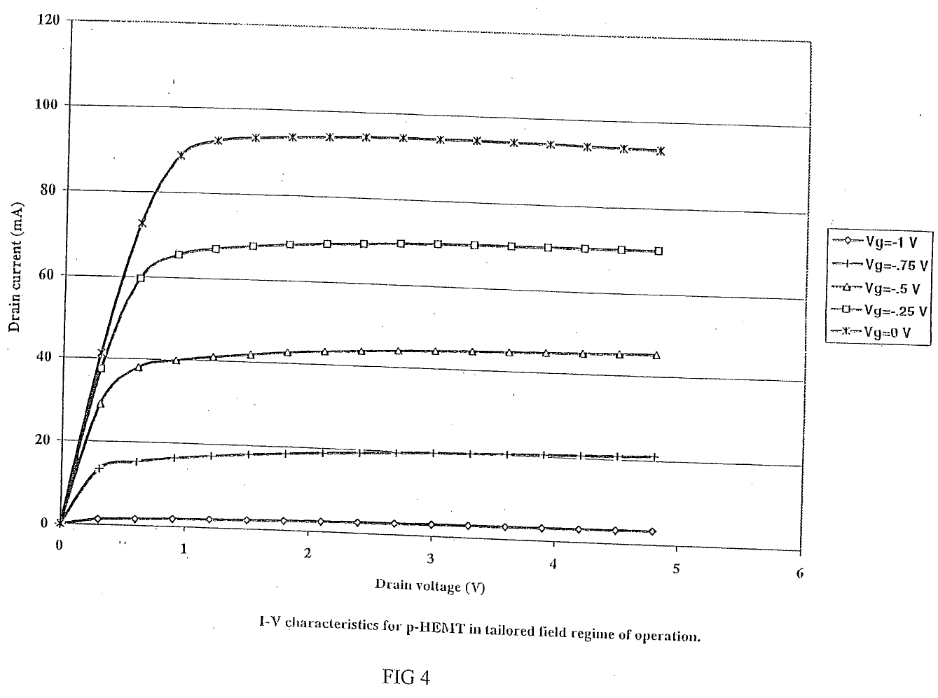

On the other hand, the spacing between the I-V curves is the same for a tri-gate p-HEMT for a case when three gates are biased separately, i.e. tailored, as shown in FIG. 4. In which case, the transconductance (gₘ) is linear as shown by the non-shaded squares in FIG. 2. Thus, this direct comparison shows that the transconductance of a HEMT with tailored fields is more linear than one for a conventional HEMT.

The versatility of the field tailoring is such that for a given particular specification the transistor performance can be improved. For example, if the gate biases are extended to positive voltages, the p-HEMT with the tailored filed significantly outperforms the transistor operating in the conventional regime. Evidence of this is shown in FIG. 2, which illustrates that the transfer curve, or the drain current Id, of the p-HEMT with a tailored field (non-shaded triangles) is more linear than a p-HEMT with three gates connected together (solid triangles). For a non-tailored transistor, as soon as gate leakage current reaches unacceptable levels, from the readability point of view, the level of the transfer curve, Id (solid triangles), as well as the transconductance curve, gₘ (solid squares), is cut off. For the transistor operating in the tailored mode, however, the critical gate leakage current is never reached, and the transconductance curve (non-shaded squares) and the transfer curve (non-shaded triangles) extend to a larger gate voltage range than the non-tailored device.

While this invention has been particularly shown and described with references to preferred embodiments thereof, it will be understood by those skilled in the art that various changes in form and details may be made therein without departing from the scope of the invention encompassed by the appended claims.

What is claimed is:

1. A heterostructured field effect transistor having a multi-gate configuration, the gate voltages being individually biased to tailor the potential field.

2. The transistor of claim 1 wherein the potential is a substantially uniform potential.

3. The transistor of claim 2 wherein the heterostructured field effect transistor is a high electron mobility transistor.

4. The transistor of claim 3 wherein the tailoring occurs along a channel of the high electron mobility transistor to create a uniform distribution of energy subbands.

5. The transistor of claim 4 wherein the uniform potential accelerates electrons as they are injected into the channel.

6. The transistor of claim 4 wherein the width of the heterostructure barrier is substantially uniform along the channel.

7. The transistor of claim 6 wherein the tailoring is accomplished by making the slope of the 2D electron gas barrier more uniform along the channel.

8. The transistor of claim 1 wherein the gates have a trapezoidal shape.

9. The transistor of claim 1 wherein the distance between two gates is submicron.

10. The transistor of claim 1 wherein the multi-gate configuration is a two-gate configuration.

11. The transistor of claim 1 wherein the multi-gate configuration is a three-gate configuration.

12. The transistor of claim 1 wherein the multi-gate configuration is a four-gate configuration.

13. The transistor of claim 1 wherein the transconductance of the transistor is substantially linear over a range of gate voltages.
